(19) United States
(12) Patent Application Publication
(10) Pub. No.: US 2013/0189446 A1
(43) Pub. Date: Jul. 25, 2013

(54) LOW PRESSURE HIGH FREQUENCY PULSED PLASMA REACTOR FOR PRODUCING NANOPARTICLES

(71) Applicants: James A. Casey, Merrill, MI (US); Vasgen Shamamian, Midland, MI (US)

(72) Inventors: James A. Casey, Merrill, MI (US); Vasgen Shamamian, Midland, MI (US)

(73) Assignee: DOW CORNING CORPORATION

(21) Appl. No.: 13/060,722

(22) PCT Filed: Sep. 1, 2009
(86) PCT No.: PCT/US09/55587

§ 371 Date: May 6, 2011

Related U.S. Application Data
(60) Provisional application No. 61/093,865, filed on Sep. 3, 2008.

(51) Int. Cl. C23C 16/24; B01F 13/00

(52) U.S. Cl. CPC C23C 16/24; B01F 13/0001; Y10S 977/891; B82Y 40/00
USPC 427/569; 118/723 R; 118/723 E; 366/139; 977/891

(57) ABSTRACT

The present invention provides a low-pressure very high frequency pulsed plasma reactor system for synthesis of nanoparticles. The system includes a chamber configured to receive at least one substrate and capable of being evacuated to a selected pressure. The system also includes a plasma source for generating a plasma from at least one precursor gas and a very high frequency radio frequency power source for providing continuous or pulsed radio frequency power to the plasma at a selected frequency. The frequency is selected based on a coupling efficiency between the pulsed radio frequency power and the plasma. Parameters of the VHF discharge and gas precursors are selected based on nanoparticle properties. The nanoparticle average size and particle size distribution are manipulated by controlling the residence time of the glow discharge (pulsing plasma) relative to the gas molecular residence time through the discharge and the mass flow rates of the nanoparticle precursor gas (or gases).

### BACKGROUND OF THE INVENTION

1. Field of the Invention

This invention relates generally to low pressure plasma reactors and more particularly to methods to produce nanoparticles in low pressure plasma reactors.

2. Description of the Related Art

The advent of nanotechnology is resulting in a paradigm shift in many technological arts because the properties of many materials change at nanoscale dimensions. For example, decreasing the dimensions of some structures to nanoscales can increase the ratio of surface area to volume, thus causing changes in the material's electrical, magnetic, reactive, chemical, structural, and thermal properties. Nanomaterials are already finding commercial application and will likely be present in everything from computers, photovoltaics, optoelectronics, medicine/pharmaceuticals, structural materials, military application, and the like within the next few decades.

Initial research efforts focused on porous silicon, but much interest and effort has now shifted from porous silicon to silicon nanoparticles. One key characteristic of small (<5 nm) silicon nanoparticles is that these particles are photo luminescent in visible light when stimulated by lower wavelength sources (UV). This is thought to be caused by a quantum confinement effect that occurs when the diameter of the nanoparticle is smaller than the exciton radius, which results in bandgap bending (i.e., increasing of the gap). FIG. 1a shows the bandgap energy (in electron volts) of a nanoparticle as a function of the nanoparticle's diameter (in nanometers). (see T. Takagahara and K. Takeda, Phys. Rev. B, 46, 15578 (1992)). Although silicon is an indirect bandgap semiconductor in bulk, silicon nanoparticles with diameters less than 5 nm emulate a direct bandgap material, which is made possible by interface trapping of excitons. Direct bandgap materials can be used in optoelectronics applications and so silicon nanoparticles may possibly be the dominant material in future optoelectronic applications. Another interesting property of nanomaterials is the lowering of the melting point following the surface-phonon instability theory. FIG. 1b shows the melting point (in degrees Celsius) of a nanomaterial formed of nanoparticles as a function of the nanoparticle's diameter (in nanometers). (M. Wautelet, J. Phys. D:Appl. Phys., 24, 343 (1991) and A. N. Goldstein, Appl. Phys. A, 62, 33 (1996)). This could lead to applications in structural materials.

Industry, universities, and laboratories have devoted substantial effort to the development of manufacturing methods and apparatuses that can be used to produce nanoparticles. Some of these techniques include microreactor plasma (R. M. Sankaran et. al., Nano. Lett. 5, 537 (2005), U.S. Patent Application Publication No. 2005/0258419 by Sankaran et. al, U.S. Patent Application Publication No. 2006/0042414 by Sankaran et. al.), aerosol thermal decomposition of silane (K. A. Littau et. al., J. Phys. Chem, 97, 1224 (1993), M. L. Ostraat et. al., J. Electrochem. Soc. 148, G265 (2001)), ultrasonication of etched silicon (G. Belomoin et. al., Appl. Phys. Lett. 80, 841 (2002)), and laser ablation of silicon (J. A. Carlisle et. al., Chem. Phys. Lett. 326, 335 (2000). Plasma discharges provide another opportunity to produce nanoparticles at high temperatures from atmospheric plasmas or at approximately room temperature with low pressure plasmas. High temperature plasmas have been investigated by N. P. Rao et. al. (U.S. Pat. Nos. 5,874,134 and 6,924,004 and U.S. Patent Application No. 2004/0046130).

Low pressure plasma has been investigated as a method to produce silicon nanoparticles since the 1990's. A group at the Tokyo Institute of Technology has produced nanocrystalline silicon particles using an ultra high vacuum (UHV) and very high frequency (VHF, ˜144 MHz) capacitively coupled plasma (S. Oda et. al. J. Non-Cryst. Solids, 198-200, 875 (1996), A. Itoh et. al. Mat. Res. Soc. Symp. Proc. 452, 749 (1997)). This approach uses a VHF plasma cell attached to a UHV chamber and decomposes silane with the plasma. A carrier gas of hydrogen or argon is pulsed into the plasma cell to push the nanoparticles, formed in the plasma, through an orifice into the UHV reactor where the particles are deposited. The high frequency allows efficient coupling from the rf power to the discharge producing a high ion density and ion energy plasma. Other groups have employed an inductively coupled plasma (ICP) reactor to make a 13.56 MHz rf plasma that has high ion energy and density. (Z. Shen and U. Kortshagen, J. Vac. Sci. Technol. A, 20, 153 (2002), A. Bapat et. al. J. Appl. Phys. 94, 1969 (2003), Z. Shen et. al. J. Appl. Phys. 94, 2277 (2003), and Y. Dong et. al. J. Vac. Sci. Technol. B 22, 1923 (2004))

The ICP reactor does not effectively produce nanoparticles and was replaced by a capacitively coupled discharge (A. Bapat et. al. Plasma Phys. Control Fusion 46, B97 (2004) and L. Mangolini et. al. Nano Lett. 5, 655 (2005)). The capacitively coupled system with a ring electrode was able to create a plasma instability that produces a constricted plasma that has an ion density and energy that is much higher than the surrounding glow discharge. This instability rotates around the discharge tube reducing the resident time of the particles in the high energy region. The capacitively coupled system produces smaller nanoparticles when the resident time is smaller because the resident time is approximately the time in which the conditions for nucleation of nanoparticles are favorable. Consequently, reducing the resident time reduces the amount of time available for the particles to nucleate from dissociate from precursor(s) molecular fragments and affords a measure of control over the particle size distribution. This method produced nanocrystalline and luminescent silicon particles. (U.S. Patent Application No. 2006/0051505) However, the radiofrequency power in the capacitively coupled system is not sufficiently coupled to the discharge. Consequently, relatively high input power (˜200 W) is needed to deliver even modest power into the plasma (˜5 W) because much of the input radiofrequency power is reflected back to the power supply. This greatly reduces the lifetime of the power supply and reduces the cost effectiveness of this technique for production of silicon nanoparticles.

### SUMMARY OF THE INVENTION

The present invention is directed to addressing the effects of one or more of the problems set forth above as improvements. The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In one embodiment of the instant invention, a low-pressure very high frequency pulsed plasma reactor system is provided for synthesis of nanoparticles. The system includes a chamber configured to receive at least one substrate and capable of being evacuated to a selected pressure. The system also includes a plasma source for generating a plasma from at least one precursor gas and a very high frequency radio frequency power source for providing continuous or pulsed radio frequency power to the plasma at a selected frequency. The frequency is selected based on a coupling efficiency between the pulsed radio frequency power and the plasma. Parameters of the VHF discharge and gas precursors are selected based on nanoparticle properties. The nanoparticle average size and particle size distribution are manipulated by controlling the residence time of the glow discharge (pulsing plasma) relative to the gas molecular residence time through the discharge and the mass flow rates of the nanoparticle precursor gas (or gases).

### BRIEF DESCRIPTION OF THE DRAWINGS

The invention may be understood by reference to the following description taken in conjunction with the accompanying drawings, in which like reference numerals identify like elements, and in which:

FIG. 1a shows the band gap energy of nanocrystalline Si as a function of particle diameter;

FIG. 1b shows the melt temperature of nanocrystalline Si as a function of particle diameter;

FIG. 2 conceptually illustrates one exemplary embodiment of a low pressure high frequency pulsed plasma reactor, in accordance with the present invention;

FIG. 3 depicts a plasma coupling efficiency as a function of frequency for an Ar/SiH₄ plasma;

FIG. 4 shows a Paschen Curve for Ar gas;

FIG. 5 is the calculated Maxwell-Boltzmann velocity distribution and particle resident time traveling through a four inch discharge for different measured pressures;

FIG. 6a is a plot of the particle size distribution as a function of plasma resident time for a 140 MHz discharge with 0.2% SiH₄ and pressure of approximately 4 Torr;

FIG. 6b is a plot of the particle size distribution as a function of plasma resident time for a 140 MHz discharge with 0.2% SiH₄ and pressure ranging from 5 to 6 Torr;

FIG. 6c is a plot of the particle size distribution as a function of plasma resident time for a 140 MHz discharge with 0.5% SiH₄ and pressure ranging from 3 to 4 Torr;

FIG. 6d is a plot of the particle size distribution as a function of plasma resident time for a 140 MHz discharge with 1% SiH₄ and pressure ranging from 3 to 4 Torr;

FIG. 7 is a plot of the particle size distribution as a function of SiH₄ mass flow rate with a decaying exponential fit;

FIG. 8a shows a 50 kX BF-TEM image of Si nanoparticles synthesized from a 127 MHz (7.87 ns plasma resident time) discharge at 0.1342 mg/min SiH₄ deposited on a carbon coated TEM grid. The insert is a selected area diffraction pattern of this image;

FIG. 8b shows a 400 kX HRTEM image of a crystalline Si nanoparticle, ˜4.7 nm diameter with an ˜1 nm thick oxide shell, deposited at the same conditions at FIG. 8a;

FIG. 8c shows a Fast Fourier Transform (FFT) of FIG. 8b illustrating the diffraction spots of the (111) plane of crystalline Si;

FIG. 8d shows a 400 kX BF-TEM image of Si nanoparticles deposited with the same conditions as FIG. 8a;

FIG. 8e show the particle size distribution histogram (including the 1-2 nm thick oxide shell) from TEM image analysis for the conditions listed in FIG. 8a;

FIG. 9a shows a 50 kX BF-TEM image of Si nanoparticles synthesized from a 140 MHz with a 50 kHz (20 μs plasma resident time) 50% depth amplitude modulated discharge at 0.25 mg/min SiH₄ deposited on a carbon coated TEM grid. The insert is a selected area diffraction pattern of this image;

FIG. 9b shows a 400 kX HRTEM image of a crystalline Si nanoparticle, ˜9.6 nm diameter with an ˜1.6 nm thick oxide shell, deposited at the same conditions at FIG. 9a;

FIG. 9c shows a Fast Fourier Transform (FFT) of FIG. 9b illustrating the diffraction spots of the (111) plane of crystalline Si;

FIG. 9d shows a 400 kX BF-TEM image of Si nanoparticles deposited with the same conditions as FIG. 9a;

FIG. 9e show the particle size distribution histogram (including the 1-2 nm thick oxide shell) from TEM image analysis for the conditions listed in FIG. 9a;

FIG. 10a shows a 50 kX BF-TEM image of Si nanoparticles synthesized from a 140 MHz with a 50 kHz (20 μs plasma resident time) 50% depth amplitude modulated discharge at 0.063 mg/min SiH₄ deposited on a carbon coated TEM grid. The insert is a selected area diffraction pattern of this image;

FIG. 10b shows a 400 kX HRTEM image of crystalline Si nanoparticles deposited at the same conditions at FIG. 10a;

FIG. 10c shows a Fast Fourier Transform (FFT) of FIG. 10b illustrating the diffraction spots of the (111) and (220) planes of crystalline Si;

FIG. 10d shows a 250 kX BF-TEM image of Si nanoparticles deposited with the same conditions as FIG. 10a;

FIG. 10e show the particle size distribution histogram (including the 1-2 nm thick oxide shell) from TEM image analysis for the conditions listed in FIG. 10a;

FIG. 11a shows a 50 kX BF-TEM image of Si nanoparticles synthesized from a 140 MHz with a 50 kHz (20 μs plasma resident time) 50% depth amplitude modulated discharge at 0.076 mg/min SiH₄ deposited on a carbon coated TEM grid. The insert is a selected area diffraction pattern of this image;

FIG. 11b shows a 400 kX HRTEM image of a crystalline Si nanoparticle, ˜20 nm diameter with an ˜1 nm thick oxide shell, deposited at the same conditions at FIG. 11a;

FIG. 11c shows a Fast Fourier Transform (FFT) of FIG. 11b illustrating the diffraction spots of the (111) and (220) planes of crystalline Si;

FIG. 11d shows a 400 kX BF-TEM image of Si nanoparticles deposited with the same conditions as FIG. 11a;

FIG. 11e show the particle size distribution histogram (including the 1-2 nm thick oxide shell) from TEM image analysis for the conditions listed in FIG. 11a;

FIG. 12a shows a 50 kX BF-TEM image of Si nanoparticles synthesized from a 140 MHz with a 50 kHz (20 μs plasma resident time) 50% depth amplitude modulated discharge at 0.072 mg/min SiH₄ deposited on a carbon coated TEM grid. The insert is a selected area diffraction pattern of this image;

FIG. 12b shows a 400 kX HRTEM image of a crystalline Si nanoparticle, ˜17 nm diameter with an ˜1 nm thick oxide shell, deposited at the same conditions at FIG. 12a;

FIG. 12c shows a Fast Fourier Transform (FFT) of FIG. 12b illustrating the diffraction spots of the (111) plane of crystalline Si;

FIG. 12d shows a 400 kX BF-TEM image of Si nanoparticles deposited with the same conditions as FIG. 12a;

FIG. 12e show the particle size distribution histogram (including the 1-2 nm thick oxide shell) from TEM image analysis for the conditions listed in FIG. 12a;

FIG. 13a shows 50 kX BF-TEM image of amorphous Si nanoparticles synthesized from a 90 MHz discharge at 0.27 mg/min SiH₄ deposited on a carbon coated TEM grid;

FIG. 13b shows a 150 kX BF-TEM image of the amorphous Si nanoparticles from the same conditions as in FIG. 13b. The particle size is ˜6 nm.

FIG. 14a shows a 25 kX BF-TEM image of amorphous Si nanoparticles synthesized from a 140 MHz with a 15 kHz (66.67 μs plasma resident time) 50% depth amplitude modulated discharge at 0.107 mg/min SiH₄ deposited on a carbon coated TEM grid. The insert is a selected area diffraction pattern of this image;

FIG. 14b shows the selected area diffraction pattern of FIG. 14a indicating the amorphous nature of the particles;

FIG. 14c shows 50 kX BF-TEM image of the amorphous Si nanoparticles deposited at the condition listed in FIG. 14a;

FIG. 14d show the particle size distribution histogram (including the 1-2 nm thick oxide shell) from TEM image analysis for the conditions listed in FIG. 14a;

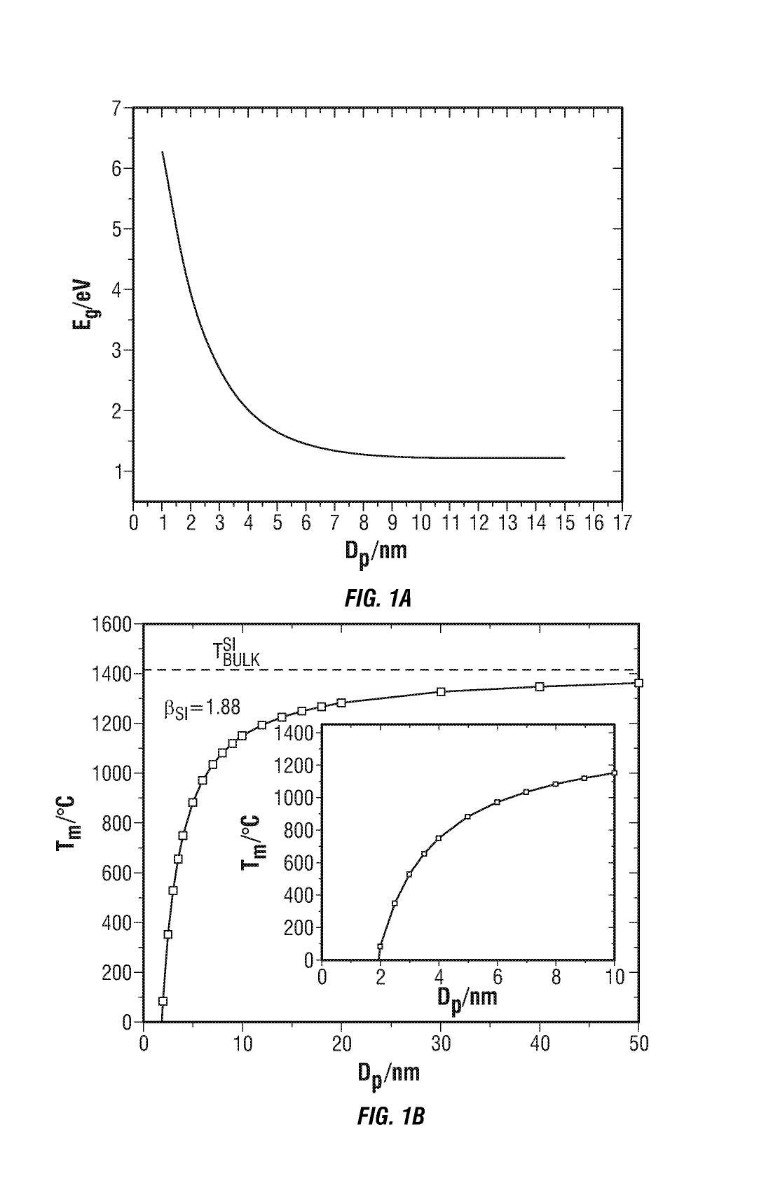

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions should be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Low pressure plasma dissociation of semiconductor containing precursors is an attractive method for producing nanoparticles via nucleation and growth processes. The techniques described herein use high frequency radio frequency plasma to break down precursor gas and then nucleate the nanoparticles. The precursors can contain hazardous and/or toxic gases or liquids, such as SiH₄, SiCl₄, H₂SiCl₂, BCl₃, B₂H₆, PH₃, GeH₄, or GeCl₄. The precursors can be used for doping or alloying nanoparticles. The process is also capable of concurrent deposition of amorphous films with nanocrystalline particles deposited with in them. Relative to conventional techniques for forming silicon nanoparticles, the high frequency plasma yields better power coupling and produces a discharge with higher ion energy and density.

Embodiments of the low pressure plasma reactors described herein use a low pressure high frequency pulsed plasma system to produce silicon nanoparticles. Pulsing the plasma enables an operator to directly set the resident time for particle nucleation and thereby control the particle size distribution and agglomeration kinetics in the plasma. For example, the operating parameters of the pulsed reactor may be adjusted to form crystalline nanoparticles or amorphous nanoparticles. Semiconductor containing precursors enter into the dielectric discharge tube where the capacitively coupled plasma, or inductively coupled plasma, is operated. Nanoparticles start to nucleate as the precursor molecules are dissociated in the plasma. When the plasma is off, or in a low ion energy state, during the pulsing cycle, the charged nanoparticles can be evacuated to the reactor chamber where they may be deposited on a substrate or subjected to further processing.

The power may be supplied via a variable frequency radio frequency power amplifier that is triggered by an arbitrary function generator to establish the high frequency pulsed plasma. In one embodiment, the radiofrequency power is capacitively coupled into the plasma using a ring electrode, parallel plates, or an anode/cathode setup in the gas. Alternatively, the radiofrequency power may be inductively coupled mode into the plasma using an rf coil setup around the discharge tube. The precursor gases can be controlled via mass flow controllers or calibrated rotometers. The pressure differential from the discharge tube to the reactor chamber can be controlled through a changeable grounded or biased orifice. Depending on the orifice size and pressures, the nanoparticle distributions into the reactor chamber may change, thus providing another process parameter that can be used to adjust the properties of the resulting nanoparticles. In one embodiment, the plasma reactor may be operated in the frequency from 30 MHz to 150 MHz at pressures from 100 mTorr to 10 Torr in the discharge tube and powers from 1 watts to 200 watts.

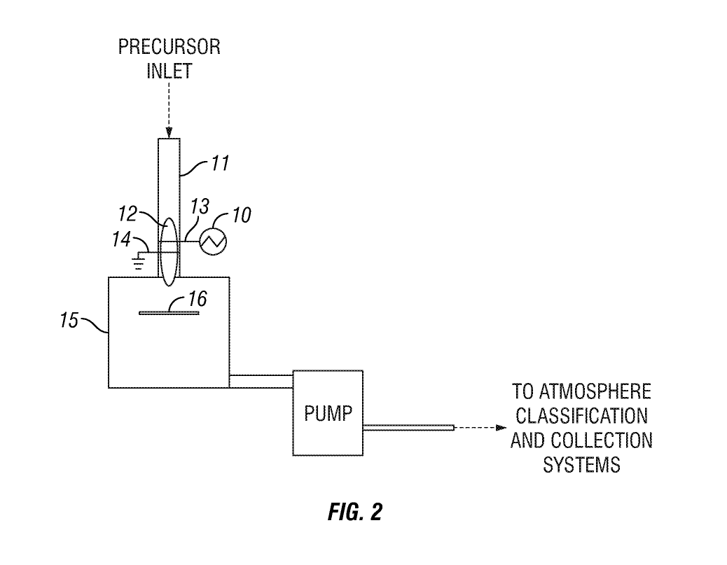

Referring now to FIG. 2, one exemplary embodiment of a low pressure high frequency pulsed plasma reactor is shown. In the illustrated embodiment, precursor gas (or gases) may be introduced to a vacuum evacuated dielectric discharge tube 11. The discharge tube 11 includes an electrode configuration 13 that is attached to a variable frequency rf amplifier 10. The other portion of the electrode 14 is either grounded, DC biased, or operated in a push-pull manner relative to electrode 13. The electrodes 13, 14 are used to couple the very high frequency (VHF) power into the precursor gas (or gases) to ignite and sustain a glow discharge or plasma 12. The precursor gas (or gases) may then be disassociated in the plasma and nucleate to form nanoparticles.

In one embodiment, the electrodes 13, 14 for a plasma source inside the dielectric tube 11 that is a flow-through showerhead design in which a VHF radio frequency biased up-stream porous electrode plate 13 is separated from a down stream porous electrode plate 14, with the pores of the plates aligned with one another. The pores could be circular, rectangular, or any other desirable shape. Alternatively, the dielectric tube 11 may enclose an electrode 13 that is coupled to the VHF radio frequency power source 10 and has a pointed tip that has a variable distance between the tip and a grounded ring 14 inside the tube 11. In this case, the VHF radio frequency power source 10 operates in a frequency range of about 30-300 MHz. In another alternative embodiment, the pointed tip 13 can be positioned at a variable distance between the tip and a VHF radio frequency powered ring 14 operated in a push-pull mode (180° out of phase). In yet another alternative embodiment, the electrodes 13, 14 include an inductive coil coupled to the VHF radio frequency power source so that radio frequency power is delivered to the precursor gas (or gases) by an electric field formed by the inductive coil. Portions of the dielectric tube 11 can be evacuated to a vacuum level between 1×10⁻⁷-500 Torr.

The nucleated nanoparticles may pass into a larger vacuum evacuated reactor 15, where collection on a solid substrate 16 (including a chuck) or into an appropriate liquid substrate/solution can occur. The solid substrate 16 can be electrically grounded, biased, temperature controlled, rotating, positioned relative the electrodes producing the nanoparticles, or on a roll-to-roll system. If deposition onto substrates is not the choice, then the particles are evacuated into a suitable pump for transition to atmospheric pressure. The nanoparticle aerosol can then be sent to an atmospheric classification system, such as a differential mobility analyzer, and collected for further functionalization or other processing.

In the illustrated embodiment, the plasma is initiated with a high frequency plasma via an rf power amplifier such as an AR Worldwide Model KAA2040 or an Electronics and Innovation 3200L. The amplifier can be driven (or pulsed) by an arbitrary function generator (e.g., a Tektronix AFG3252 function generator) that is capable of producing up to 200 watts of power from 0.15 to 150 MHz. In various embodiments, the arbitrary function may be able to drive the power amplifier with pulse trains, amplitude modulation, frequency modulation, or different waveforms. The power coupling between the amplifier and the precursor gas typically increases as the frequency of the rf power increases. The ability to drive the power at a higher frequency may therefore allow more efficient coupling between the power supply and discharge. The increased coupling may be manifested as a decrease in the voltage standing wave ratio (VSWR).

$$V S W R = \frac{1 + p}{1 - p} , \qquad ( 1 )$$

where p is the reflection coefficient,

$$p = \frac{{Z}_{P} - {Z}_{C}}{{Z}_{C} + {Z}_{P}} , \qquad ( 2 )$$

with Z_{P} and Z_{C} representing the impedance of the plasma and coil respectively. At frequencies below 30 MHz, only 2-15% of the power is delivered to the discharge. This has the effect of producing high reflected power in the rf circuit that leads to increased heating and limited lifetime of the power supply. In contrast, higher frequencies allow more power to be delivered to the discharge, thereby reducing the amount of reflected power in the rf circuit and decreasing the heating of the power supply, which may increase the lifetime of the power supply.

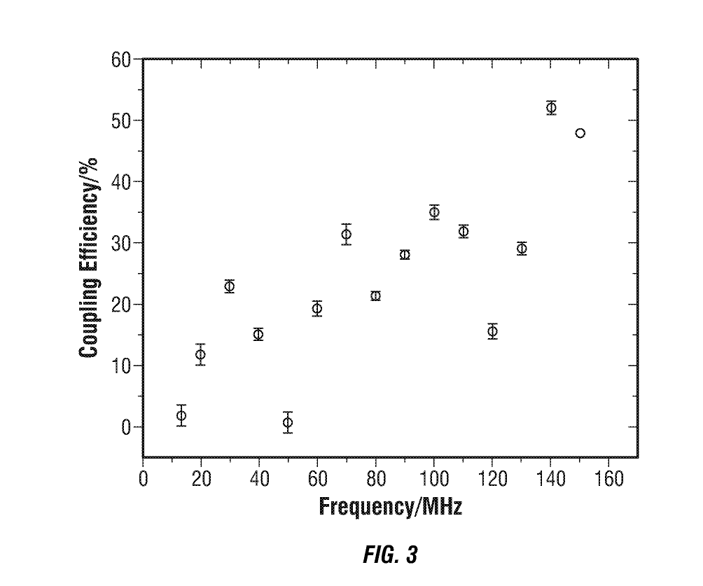

FIG. 3 shows the plasma coupling efficiency as a function of frequency of the rf power (in MHz) for an Ar/SiH₄ discharge at 1.4 Torr. This figure demonstrates that increasing the rf frequency generally increases the plasma coupling efficiency. The increase is not necessarily monotonic, at least in part because parasitic resonances form at some of the higher frequencies that occur due to the capacitance and inductance of the coil, plasma, and length of the rf cable. These parasitic resonances tend to reduce the coupling efficiency. However, ˜50% power coupling can be achieved by operating the rf power source at around 140 MHz. The ion energy and density of the discharge can also be adjusted by varying the power and frequency of the power supply. The pulsing function of the system allows for controlled tuning of the particle resident time in the plasma, which is a key measure that determines the size of the nanoparticles. By decreasing the ON time of the plasma, the nucleating particles have less time to agglomerate and therefore the size of the nanoparticles may be reduced on average (i.e., the nanoparticle distribution may be shifted to lower particle sizes). Operating at the higher frequency and having the ability to pulse the plasma allows this method to produce the same conditions as in conventional constricted/filament discharge techniques that use a plasma instability to produce the high ion energies/densities, but with the additional advantage that users can control operating conditions to select and produce a wide variety of nanoparticle sizes.

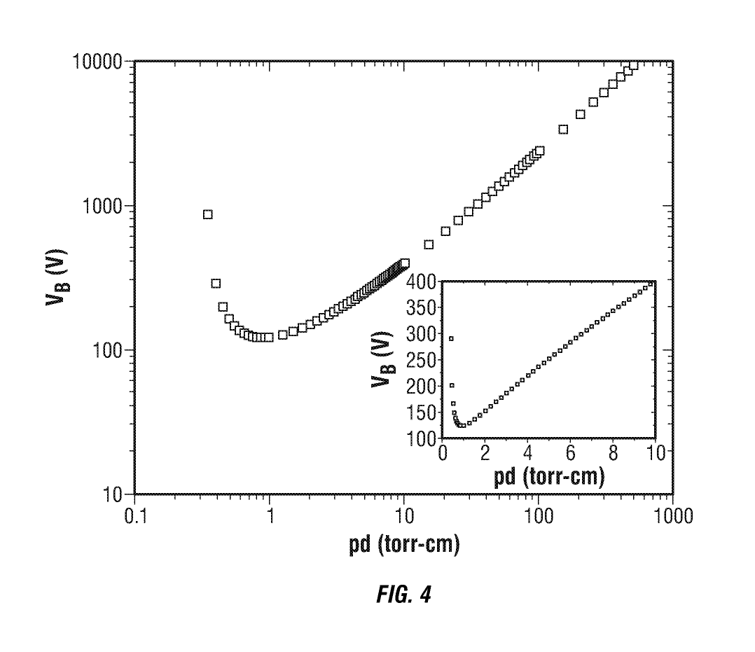

Referring back to FIG. 2, the ignition point of the discharge tube 11 can be determined. The ignition point corresponds to the electrical potential in the precursor gas that is just high enough to cause breakdown and is given by the Paschen Law (dc model),

$${V}_{B} = \frac{B \cdot pd}{ln ( pd ) - C} , \qquad ( 3 )$$

where V_{B} is the breakdown voltage of the gas, p is the pressure, d is the distance between the electrodes, and B and C are gas dependent constants. FIG. 4 shows the Paschen curve for Ar (log-log scale). The vertical axis indicates the breakdown voltage (in volts) and the horizontal axis indicates the precursor gas pressure in (Torr-cm). The insert is a zoomed region near the minimum with linear axis. The dc model of breakdown can be used in this system since the oscillating frequencies are sufficiently high. For lower frequency ac/rf discharges, ≦3.5 MHz, the breakdown voltage has a second (local) minimum at a pressure higher than the global breakdown voltage; see Y. P. Raizer Gas Discharge Physics, Springer-Verlag, 1997 pg. 162-166.

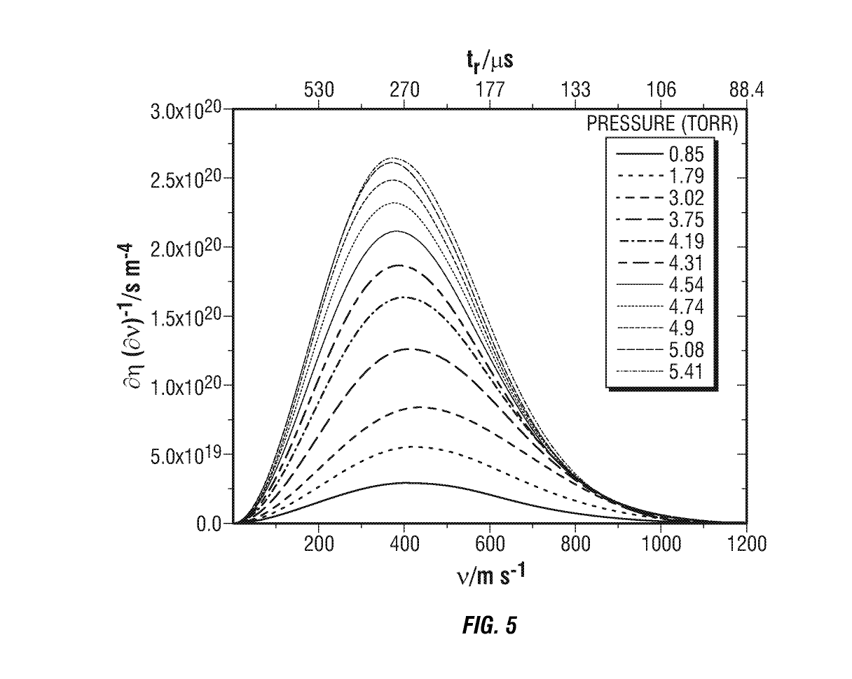

FIG. 5 is a plot of the Maxwell-Boltzmann velocity distribution function,

$$\frac{\partial n}{\partial v} = \frac{2 N}{{π}^{1 / 2}} {( \frac{m}{2 kT} )}^{3 / 2} {v}^{2} {e}^{- {mv}^{2} / 2 kT} \qquad ( 4 )$$

as a function of gas velocity and resident time through a four inch glow discharge. N is the number of molecules, m is the molecular mass, k is the Boltzmann's constant, and T is the gas temperature in equation 4. The velocity distributions were calculated from pressure increases due to dissociation of molecules in a glow discharge for the different pressures reported. The significance of this function in the synthesis of nanoparticles is that since there is a distribution of velocities within the glow discharge activation region, the resulting particles have a particle size distribution. Controlling the plasma residence time (i.e. the period of higher ionization of precursor molecules) relative to the residence time through the plasma can lead to minimizing the Maxwellian distribution of particle sizes.

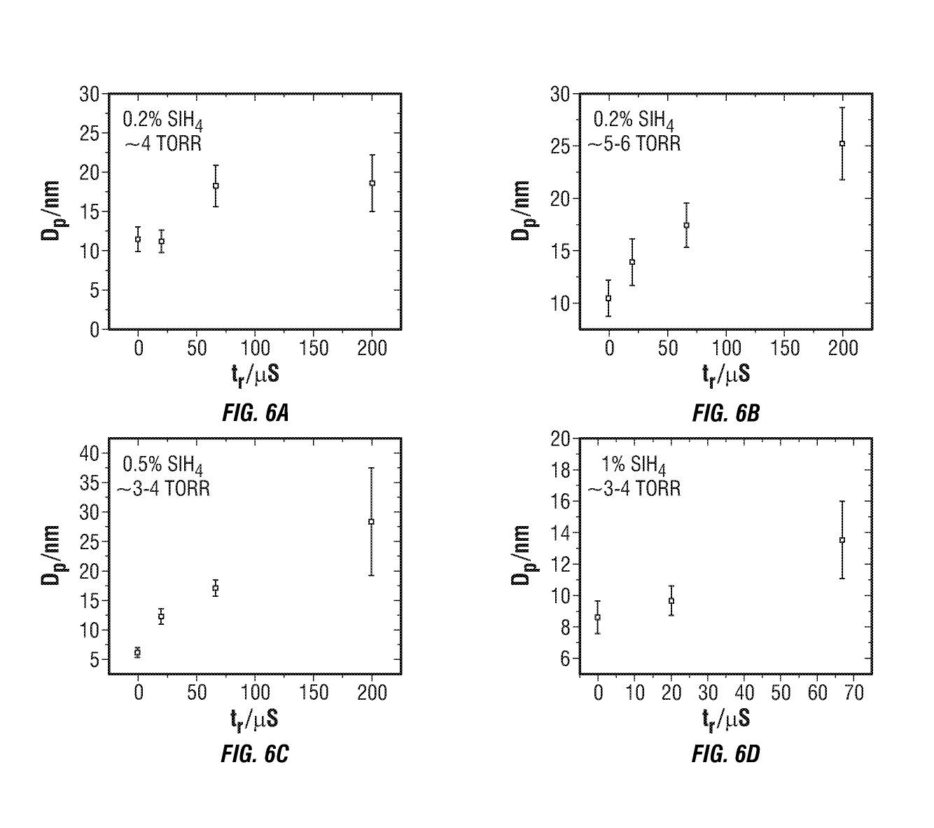

FIG. 6 shows four plots of the particle size distribution (measured with oxide shells) as a function to plasma residence time for amplitude modulated SiH₄/Ar discharges, illustrating the control of the particle size and distribution. In FIG. 6, a) displays this for a discharge consisting of 0.2% SiH₄ with a discharge tube pressure of approximately 4 Torr, b) is for a 0.2% SiH₄ discharge with pressure ranging from 5 to 6 Torr, c) is a discharge containing 0.5% SiH₄ at a pressure between 3 and 4 Torr, and d) is a 1% SiH₄ discharge in the 3 to 4 Torr range. In all cases, the average particle size and particle size distribution increases with increasing plasma residence time. This is due to the increasing period of the higher ion density and energy of the longer residence time discharges. At these longer times, the Si nanoparticles have a higher probability to start to nucleate into larger particles. The broader particle size distributions observed at longer residence times is due to the Maxwellian velocity distribution shown in FIG. 5. Smaller average particle size and tighter particle size distributions occur a lower plasma residence times since the time period of higher ion energy/density is less, thus minimizing the Maxwellian distribution leading to a broad particle size distribution.

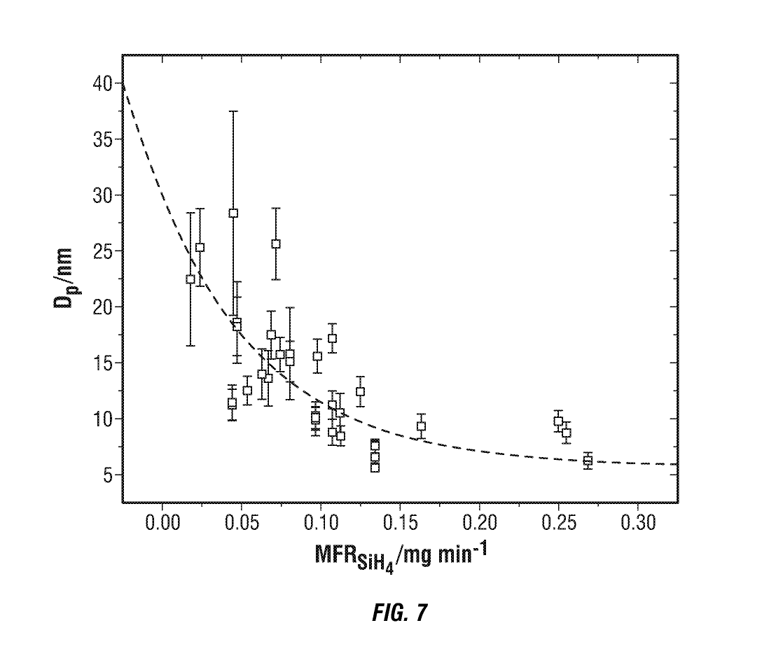

FIG. 7 is a plot of the particle size distribution (measured with the oxide shells) of Si nanoparticles as a function of SiH₄ mass flow rate. The dashed line in the figure is a fitted exponential decay function used to illustrate the decreasing nature of the average particle size and decreasing particle size distribution as the SiH₄ mass flow rate increases. At lower precursor mass flow rates, the nucleation of nanoparticles in the glow discharge activation region is concentration limited. This combined with the Maxwellian velocity distribution of the gas leads to a broader particle sized distribution.

The techniques described herein can be used to form various kinds of nanoparticles and/or collections of nanoparticles. Several examples of embodiments that can be used to different purposes are described below. However, persons of ordinary skill in the art having benefit of the present disclosure should appreciate that these embodiments are intended to be illustrative and not to be limiting.

In one embodiment, the mean particle diameter of nanoparticles can be controlled by controlling the plasma residence time and a high ion energy/density region of a VHF radio frequency low pressure glow discharge can be controlled relative to at least one precursor gas molecular residence time through the discharge. The size distribution of the nanoparticles can also be controlled by controlling the plasma residence time, a high ion energy/density region of the VHF radio frequency low pressure glow discharge relative to said at least one precursor gas molecular residence time through the discharge. Typically, the lower the plasma residence time of a VHF radio frequency low pressure glow discharge relative to the gas molecular residence time, the smaller the mean core nanoparticle diameter at constant operating conditions. The operating conditions may be defined by the discharge drive frequency, drive amplitude, discharge tube pressure, chamber pressure, plasma power density, precursor mass flow rates, and collection distance from plasma source electrodes. For example, as the plasma residence time of a VHF radio frequency low pressure glow discharge relative to the gas molecular residence time increases, the mean core nanoparticle diameter follows an exponential growth model of y=y₀−exp(−tᵣ/C), where y is the mean nanoparticle diameter, y₀ is the offset, tᵣ is the plasma residence time, and C is a constant. The particle size distribution may also increase as the plasma residence time increases under otherwise constant operating conditions.

In another embodiment, the mean particle diameter of nanoparticles (as well as the nanoparticle size distribution) can be controlled by controlling a mass flow rate of at least one precursor gas in a VHF radio frequency low pressure glow discharge for controlling the nanoparticle mean particle diameter. For example, as the mass flow rate of precursor gas (or gases) increases in the VHF radio frequency low pressure plasma discharge, the synthesized mean core nanoparticle diameter may decrease following an exponential decay model of the form y=y₀+exp(−MFR/C′), where y is the mean nanoparticle diameter, yₒ is the offset, MFR is the precursor mass flow rate, and C′ is a constant, for constant operating conditions. Typical operating conditions may include discharge drive frequency, drive amplitude, discharge tube pressure, chamber pressure, plasma power density, gas molecule residence time through the plasma, and collection distance from plasma source electrodes. The synthesized mean core nanoparticle particle size distribution may also decrease as an exponential decay model of the form y=y₀+exp(−MFR/K), where y is the mean nanoparticle diameter, y₀ is the offset, MFR is the precursor mass flow rate, and K is a constant, for constant operating conditions. Larger particle size distributions occur at lower mass flow rates because the nucleation and growth of nanoparticles in the glow discharge activation region is concentration limited.

In yet another embodiment, nanoparticles having varying agglomeration lengths can be produced by nucleating the nanoparticles from at least one precursor gas in a VHF radio frequency low pressure plasma discharge and collecting the nucleated nanoparticles by controlling the mean free path of the nanoparticles as an aerosol, thus allowing particle—particle interactions prior to collection. The nucleated nanoparticles may be collected on a solid substrate within a vacuum environment where the collection distance is greater than the mean free path of the particles controlled via the pressure. The agglomeration lengths of the nanoparticles can thereby be controlled. Alternatively, the nucleated nanoparticles may be collected in a liquid substrate within a vacuum environment where the collection distance is greater than the mean free path of the particles controlled via the pressure thus controlling the agglomeration lengths of the nanoparticles. The further away the substrate is from the nucleation region (plasma discharge), the longer the agglomerations are at a constant pressure. The synthesized nanoparticles may be evacuated out of the low pressure environment into an atmospheric environment as an aerosol so that the agglomeration length is at least partially controlled by the concentration of the aerosol.

In yet another alternative embodiment, nanoparticles can be produced by synthesizing crystalline or amorphous core nanoparticles using VHF radio frequency low pressure plasma that is discharged in a low pressure environment by pulsing the discharge to control the plasma residence time. For example, the amorphous core nanoparticles can be synthesized at increased plasma residence time relative to the precursor gas molecular residence time through a VHF radio frequency low pressure plasma discharge. Alternatively, crystalline core nanoparticles can be synthesized at lower plasma residence times at the same operating conditions of discharge drive frequency, drive amplitude, discharge tube pressure, chamber pressure, plasma power density, gas molecule residence time through the plasma, and collection distance from plasma source electrodes.

Alloyed and/or doped nanoparticles can be formed by mixing at least one nanoparticle precursor gas with at least one alloying and/or dopant precursor gas in a VHF radio frequency low pressure plasma discharge. The mean nanoparticle diameter is controlled by setting the plasma residence time relative to the precursor molecular residence time through the plasma discharge by pulsing the plasma. The nanoparticle size distribution is controlled by setting the plasma residence time relative to the precursor molecular residence time through the plasma discharge by pulsing the plasma.

### EXAMPLES

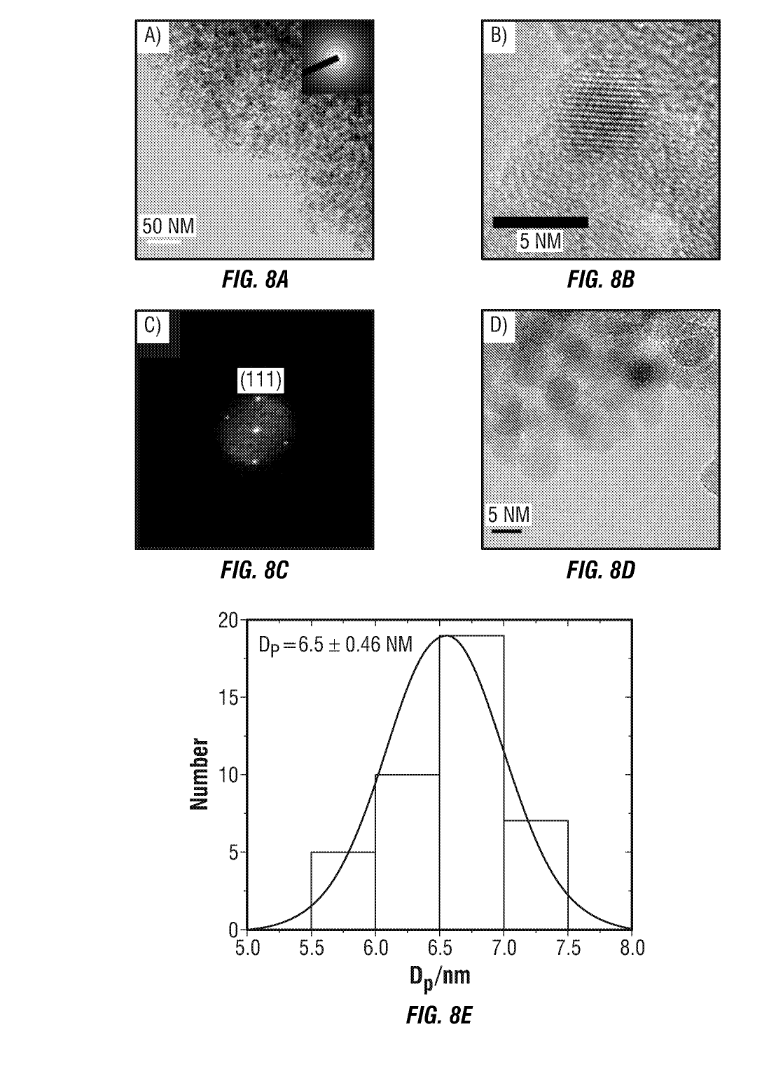

FIG. 8 shows the results of a Si nanoparticle deposition via a c-LPHFPP reactor such as shown in FIG. 2. The precursor gases consisted of 16.67 sccm Ar with 5 sccm SiH₄ (2% in Ar) yielding a SiH₄ mass flow rate of 0.1342 mg/min. The glow discharge operated at 127 MHz with a power density of 202 watts/cm² and a pressure of 3.75 Torr. The synthesized Si nanoparticles were collected in vacuum on a rotating (4 rpm) carbon coated copper Transmission Electron Microscope (TEM) grid positioned 2.5 cm from the quartz dielectric tube. FIG. 8a) is a 50 kX bright field TEM (BF-TEM) image of the particles synthesized at this condition. The insert of FIG. 8a is the selected area diffraction pattern of the image. The diffraction ring pattern illustrates that crystalline particles have been deposited. Energy dispersive X-ray spectroscopy (EDS) showed a strong peak at 1.8 keV indicating that the crystalline particles are Si (not shown). FIG. 8b) is 400 kX HRTEM image of a 4.7 nm crystalline Si core nanoparticle with a 1 nm thick oxide coating. This oxide coating forms once the sample is removed from the reactor and exposed to air or other reactive atmosphere prior to imaging with the TEM. Multiple atomic lattice fringes are visible with the prominent one being the (111) plane of cubic diamond lattice Si. This is known because the spacing of the fringes is 0.31 nm. FIG. 8c) is a Fast Fourier Transform (FFT) of the image in FIG. 8b. The FFT transforms the TEM image from real space to reciprocal lattice space, enabling the repeating patterns for the HRTEM image to be displayed as diffraction spots. With the spacing known from the HRTEM image, the g-vector distance in the FFT is measured and used to determine the proper d-space value for the lattice plane which is used to determine the composition of the nanoparticle. The diffraction spots shown in FIG. 8c have a d-spacing of 3.13 Å (g-value of 0.319 Å⁻¹) that corresponds to the (111) lattice plane of diamond cubic structure of Si. FIG. 8d) shows a 400 kX BF-TEM image of the Si nanoparticles deposited from this condition. FIG. 8e) is the particle size distribution measured from the TEM images (including the oxide shell) fitted with a Gaussian distribution. The average diameter was 6.5 nm with a standard deviation of 0.46 nm.

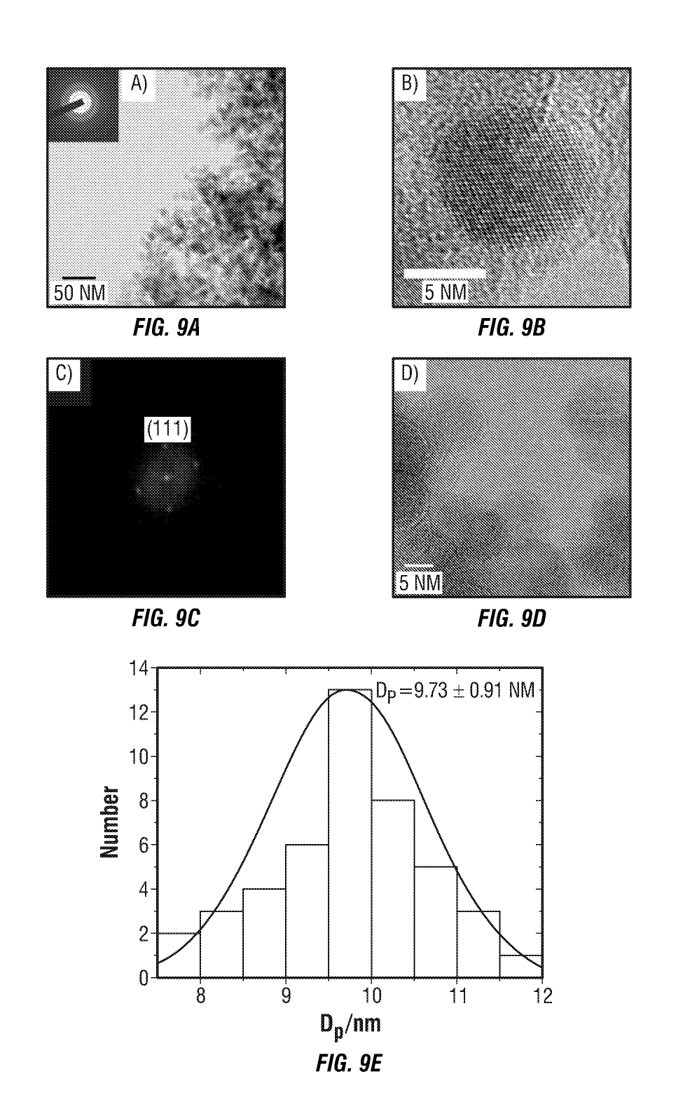

FIG. 9 shows the results of a Si nanoparticle deposition via a c-LPHFPP reactor such as shown in FIG. 2. The precursor gases consisted of 9.3 sccm Ar with 9.3 sccm SiH₄ (2% in Ar) yielding a SiH₄ mass flow rate of 0.25 mg/min. The glow discharge operated at 140 MHz with amplitude modulation carrier sine wave of 50 kHz at 50% depth (plasma residence time of 20 μs), power density of 177 watts/cm², and a pressure of 3.5 Torr. The synthesized Si nanoparticles were collected in vacuum on a rotating (4 rpm) carbon coated copper Transmission Electron Microscope (TEM) grid positioned 2.5 cm from the quartz dielectric tube. FIG. 9a) is a 50 kX bright field TEM (BF-TEM) image of the particles synthesized at this condition. The insert of FIG. 9a is the selected area diffraction pattern of the image. The diffraction ring pattern illustrates that crystalline particles have been deposited. Energy dispersive X-ray spectroscopy (EDS) showed a strong peak at 1.8 keV indicating that the crystalline particles are Si (not shown). FIG. 9b) is 400 kX HRTEM image of a 9.6 nm crystalline Si core nanoparticle with a 1.6 nm thick oxide coating. This oxide coating forms once the sample is removed from the reactor and exposed to air or other reactive atmosphere prior to imaging with the TEM. Multiple atomic lattice fringes are visible with the prominent one being the (111) plane of cubic diamond lattice Si. FIG. 9c) is a Fast Fourier Transform (FFT) of the image in FIG. 9b. The diffraction spots shown in FIG. 9c have a d-spacing of 3.13 Å (g-value of 0.319 Å⁻¹) that corresponds to the (111) lattice plane of diamond cubic structure of Si. FIG. 9d) shows a 400 kX BF-TEM image of the Si nanoparticles deposited from this condition. FIG. 9e) is the particle size distribution measured from the TEM images (including the oxide shell) fitted with a Gaussian distribution. The average diameter was 9.73 nm with a standard deviation of 0.91 nm.

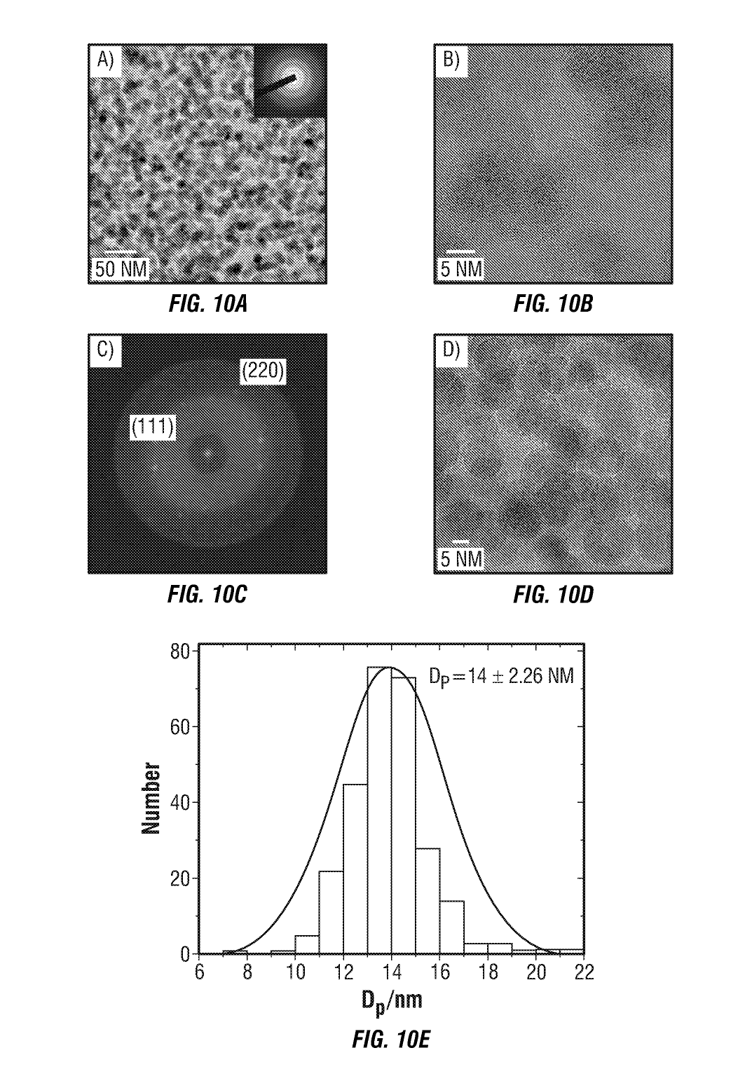

FIG. 10 shows the results of a Si nanoparticle deposition via a c-LPHFPP reactor such as shown in FIG. 2. The precursor gases consisted of 21 sccm Ar with 2.34 sccm SiH₄ (2% in Ar) yielding a SiH₄ mass flow rate of 0.063 mg/min. The glow discharge operated at 140 MHz with amplitude modulation carrier sine wave of 50 kHz at 50% depth (plasma residence time of 20 μs), power density of 180 watts/cm², and a pressure of 5.45 Torr. The synthesized Si nanoparticles were collected in vacuum on a rotating (4 rpm) carbon coated copper Transmission Electron Microscope (TEM) grid positioned 2.5 cm from the quartz dielectric tube. FIG. 10a) is a 50 kX bright field TEM (BF-TEM) image of the particles synthesized at this condition. The insert of FIG. 10a is the selected area diffraction pattern of the image. The diffraction ring pattern illustrates that crystalline particles have been deposited. Energy dispersive X-ray spectroscopy (EDS) showed a strong peak at 1.8 keV indicating that the crystalline particles are Si (not shown). FIG. 10b) is 400 kX HRTEM image of the crystalline Si core nanoparticles with an oxide coating. This oxide coating forms once the sample is removed from the reactor and exposed to air or other reactive atmosphere prior to imaging with the TEM. Multiple atomic lattice fringes are visible with the prominent one being the (111) plane of cubic diamond lattice Si. FIG. 10c) is a Fast Fourier Transform (FFT) of the image in FIG. 10b. The diffraction spots shown in FIG. 10c have a d-spacing of 3.13 Å (g-value of 0.319 Å⁻¹) that corresponds to the (111) lattice plane and 1.92 Å (g-value of 0.521 Å⁻¹) that corresponds to the (220) lattice plane of diamond cubic structure of Si. FIG. 10d) shows a 250 kX BF-TEM image of the Si nanoparticles deposited from this condition. FIG. 10e) is the particle size distribution measured from the TEM images (including the oxide shell) fitted with a Gaussian distribution. The average diameter was 14 nm with a standard deviation of 2.26 nm.

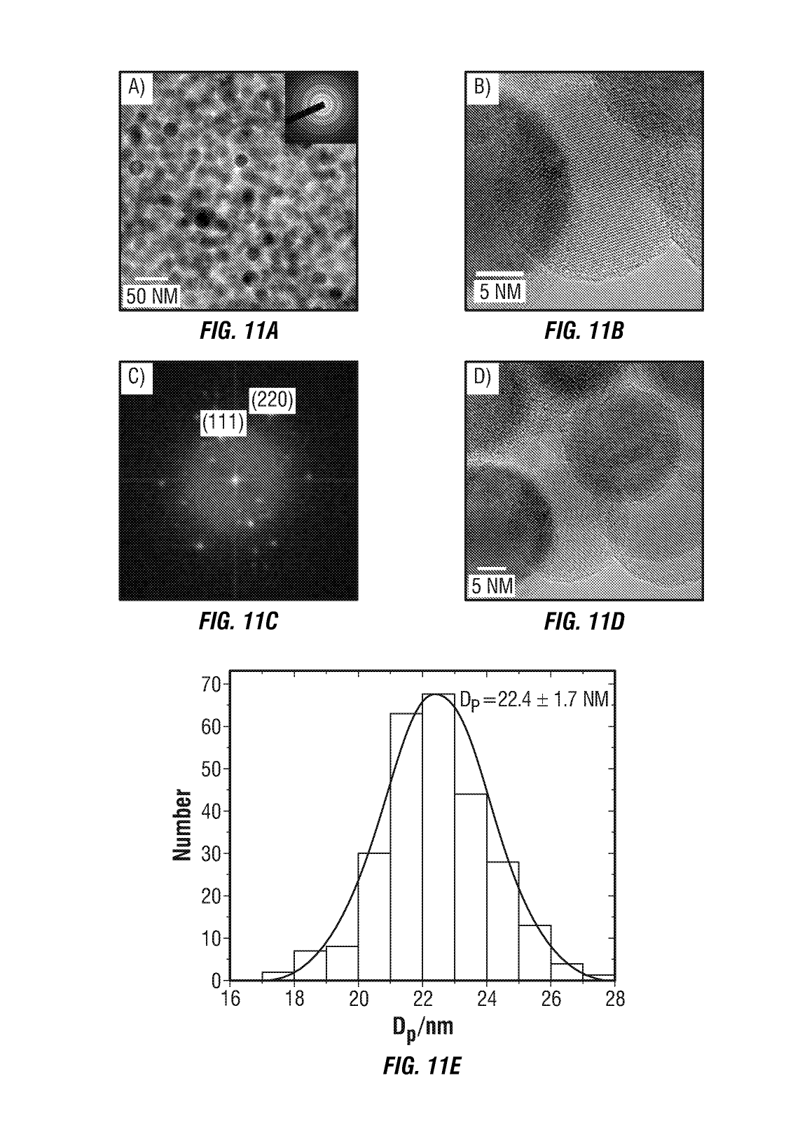

FIG. 11 shows the results of a Si nanoparticle deposition via a c-LPHFPP reactor such as shown in FIG. 2. The precursor gases consisted of 8.5 sccm Ar with 2.83 sccm SiH₄ (2% in Ar) yielding a SiH₄ mass flow rate of 0.076 mg/min. The glow discharge operated at 140 MHz with amplitude modulation carrier sine wave of 50 kHz at 50% depth (plasma residence time of 20 μs), power density of 171 watts/cm², and a pressure of 4.8 Torr. The synthesized Si nanoparticles were collected in vacuum on a rotating (4 rpm) carbon coated copper Transmission Electron Microscope (TEM) grid positioned 2.5 cm from the quartz dielectric tube. FIG. 11a) is a 50 kX bright field TEM (BF-TEM) image of the particles synthesized at this condition. The insert of FIG. 11a is the selected area diffraction pattern of the image. The diffraction ring pattern illustrates that crystalline particles have been deposited. Energy dispersive X-ray spectroscopy (EDS) showed a strong peak at 1.8 keV indicating that the crystalline particles are Si (not shown). FIG. 11b) is 400 kX HRTEM image of a 20 nm crystalline Si core nanoparticle with a 1 nm thick oxide coating. This oxide coating forms once the sample is removed from the reactor and exposed to air prior to imaging with the TEM. Multiple atomic lattice fringes are visible with the prominent one being the (111) plane of cubic diamond lattice Si. FIG. 11c) is a Fast Fourier Transform (FFT) of the image in FIG. 11b. The diffraction spots shown in FIG. 11c have a d-spacing of 3.13 Å (g-value of 0.319 Å⁻¹) that corresponds to the (111) lattice plane and 1.92 Å (g-value of 0.521 Å⁻¹) that corresponds to the (220) lattice plane of diamond cubic structure of Si. The extra spots occur from multiple scattering due to the overlapping of the crystalline nanoparticles in FIG. 11b. FIG. 11d) shows a 400 kX BF-TEM image of the Si nanoparticles deposited from this condition. FIG. 11e) is the particle size distribution measured from the TEM images (including the oxide shell) fitted with a Gaussian distribution. The average diameter was 22.4 nm with a standard deviation of 1.7 nm.

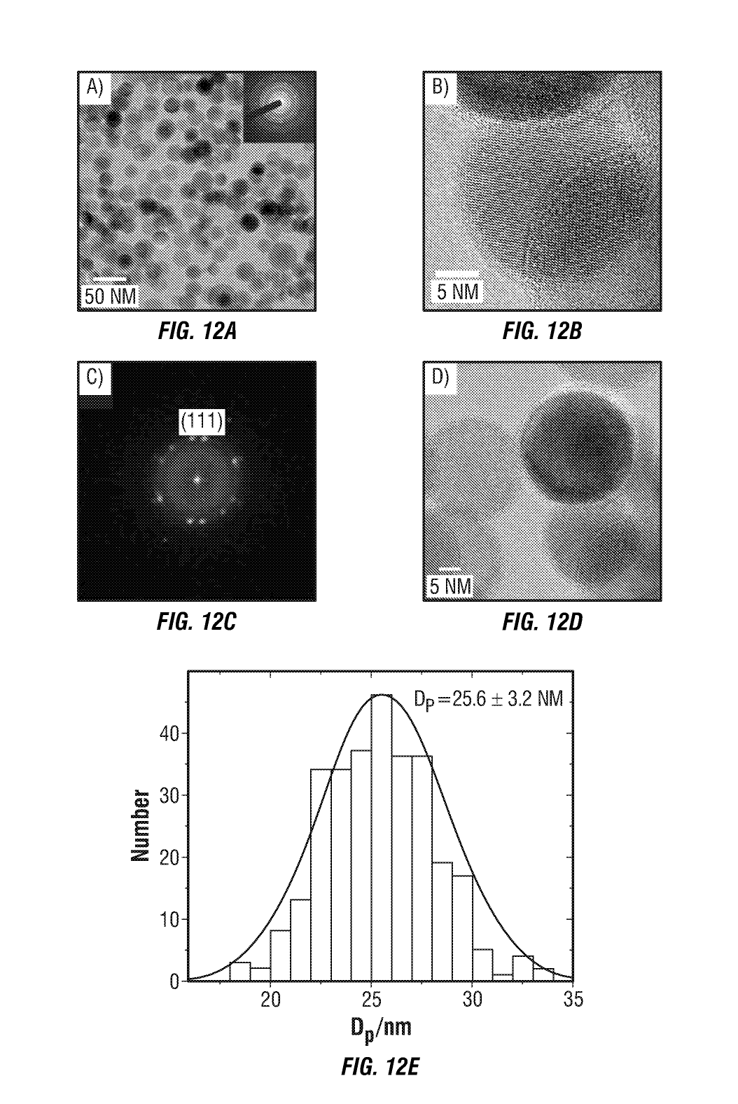

FIG. 12 shows the results of a Si nanoparticle deposition via a c-LPHFPP reactor such as shown in FIG. 2. The precursor gases consisted of 8 sccm Ar with 2.67 sccm SiH₄ (2% in Ar) yielding a SiH₄ mass flow rate of 0.072 mg/min. The glow discharge operated at 140 MHz with amplitude modulation carrier sine wave of 50 kHz at 50% depth (plasma residence time of 20 μs), power density of 167 watts/cm², and a pressure of 5.3 Torr. The synthesized Si nanoparticles were collected in vacuum on a rotating (4 rpm) carbon coated copper Transmission Electron Microscope (TEM) grid positioned 2.5 cm from the quartz dielectric tube. FIG. 12a) is a 50 kX bright field TEM (BF-TEM) image of the particles synthesized at this condition. The insert of FIG. 12a is the selected area diffraction pattern of the image. The diffraction ring pattern illustrates that crystalline particles have been deposited. Energy dispersive X-ray spectroscopy (EDS) showed a strong peak at 1.8 keV indicating that the crystalline particles are Si (not shown). FIG. 12b) is 400 kX HRTEM image of a 17 nm crystalline Si core nanoparticle with a 1 nm thick oxide coating. This oxide coating forms once the sample is removed from the reactor and exposed to air prior to imaging with the TEM. Multiple atomic lattice fringes are visible with the prominent one being the (111) plane of cubic diamond lattice Si. FIG. 12c) is a Fast Fourier Transform (FFT) of the image in FIG. 12b. The diffraction spots shown in FIG. 12c have a d-spacing of 3.13 Å (g-value of 0.319 Å⁻¹) that corresponds to the (111) lattice plane of diamond cubic structure of Si. FIG. 12d) shows a 400 kX BF-TEM image of the Si nanoparticles deposited from this condition. FIG. 12e) is the particle size distribution measured from the TEM images (including the oxide shell) fitted with a Gaussian distribution. The average diameter was 25.6 nm with a standard deviation of 3.2 nm.

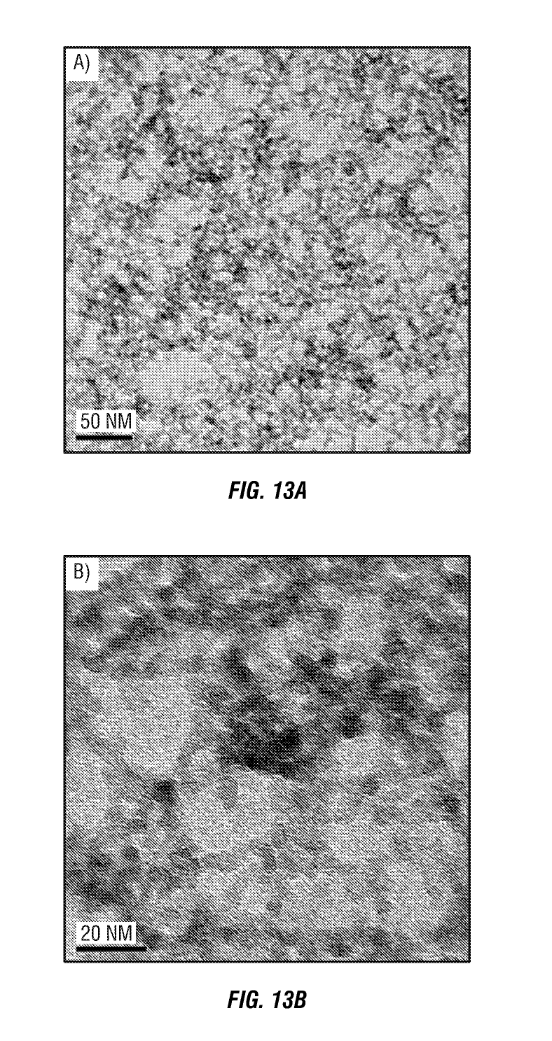

FIG. 13 shows the results of a Si nanoparticle deposition via a c-LPHFPP reactor such as shown in FIG. 2. The precursor gases consisted of 10 sccm SiH₄ (2% in Ar) yielding a SiH₄ mass flow rate of 0.27 mg/min. The glow discharge operated at 90 MHz with a power density of 3.15 watts/cm², and a pressure of 4.61 Torr. The synthesized Si nanoparticles were collected in vacuum on a carbon coated copper Transmission Electron Microscope (TEM) grid positioned 2.5 cm from the quartz dielectric tube. FIG. 13a) is a 50 kX bright field TEM (BF-TEM) image of the particles synthesized at this condition. The selected area diffraction pattern of the image showed diffused rings indicating amorphous particles (not shown). Energy dispersive X-ray spectroscopy (EDS) showed a strong peak at 1.8 keV indicating that the particles are Si (not shown). FIG. 13b) is 150 kX HRTEM image of the amorphous Si nanoparticles. The particles have all fused together in fractal type agglomerates with diameters approximately 6 nm.

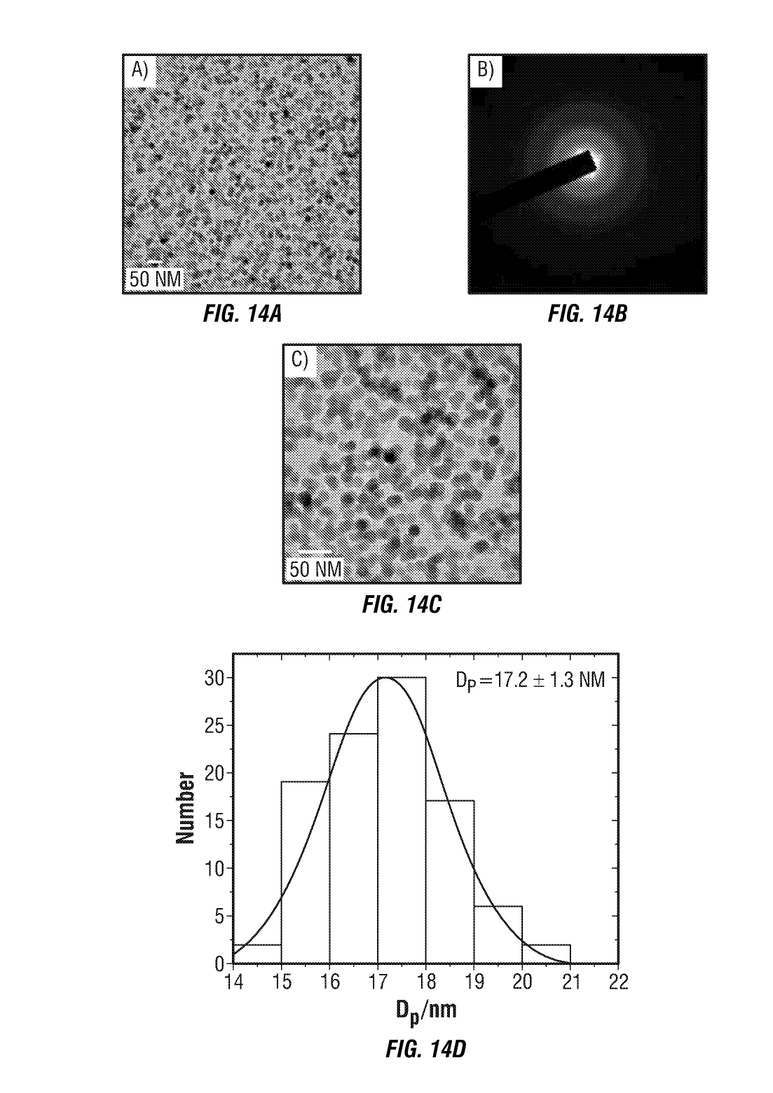

FIG. 14 shows the results of a Si nanoparticle deposition via a c-LPHFPP reactor such as shown in FIG. 2. The precursor gases consisted of 12 sccm Ar with 4 sccm SiH₄ (2% in Ar) yielding a SiH₄ mass flow rate of 0.107 mg/min. The glow discharge operated at 140 MHz with amplitude modulation carrier sine wave of 515 kHz at 50% depth (plasma residence time of 66.67 μs), power density of 202 watts/cm², and a pressure of 3.61 Torr. The synthesized Si nanoparticles were collected in vacuum on a rotating (6 rpm) carbon coated copper Transmission Electron Microscope (TEM) grid positioned 2.5 cm from the quartz dielectric tube. FIG. 14a) is a 25 kX bright field TEM (BF-TEM) image of the particles synthesized at this condition. Energy dispersive X-ray spectroscopy (EDS) showed a strong peak at 1.8 keV indicating that the particles are Si (not shown). FIG. 14b) is the selected area diffraction pattern from FIG. 14a. Notice the diffused rings that indicate the particles synthesized are amorphous Si nanoparticles. FIG. 14c) shows a 50 kX BF-TEM image of the amorphous Si nanoparticles deposited from this condition. FIG. 14d) is the particle size distribution measured from the TEM images (including the oxide shell) fitted with a Gaussian distribution. The average diameter was 17.2 nm with a standard deviation of 1.3 nm.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope of the invention. Accordingly, the protection sought herein is as set forth in the claims below.

1. A low-pressure high-frequency pulsed plasma reactor system, comprising:
flow rate controllers for controlling rates of at least one precursor gas;
a chamber configured to receive at least one substrate and capable of being evacuated to a selected pressure;
a plasma source for generating a plasma from said at least one precursor gas; and
a very high frequency radio frequency power source for providing pulsed radio frequency power to the plasma at a radio frequency selected based on a coupling efficiency between the pulsed radio frequency power source and the plasma, wherein at least one parameter of the radio frequency power is selectable based on at least one property of nanoparticles formed by supplying the pulsed radio frequency power to the plasma.

2. The system of claim 1, wherein the flow rate controllers comprise at least one of a gas flow rate controller, a mass flow rate controller, an electrical controlled mass flow controller, or a precision rotameter.

3. The system of claim 1, comprising a dielectric tube that can be evacuated to a vacuum level that is less than atmospheric pressure while said at least one precursor gas is being flowed.

4. The system of claim 3, wherein the vacuum level is between 1×10⁻⁷-500 Torr.

5. The system of claim 4, where the vacuum level is between 100-300 Torr.

6. The system of claim 4, where the vacuum level is between 1×10⁻⁷-1×10⁻³ Torr.

7. The system of claim 1, wherein the plasma source comprises a dual ring electrode, where the up stream ring is biased to the VHF radio frequency and the down stream ring is grounded or biased to VHF radio frequency operated with the ring electrodes operating in push-pull (180° out of phase).

8. The system of claim 1, wherein the plasma source comprises at least one of:
a dielectric tube enclosing an electrode that is coupled to the VHF radio frequency power source, the electrode having a pointed tip that has a variable distance between the tip and a grounded ring inside the tube, and wherein the VHF radio frequency power source operates in a frequency range of about 30-300 MHz, and wherein the distance between the VHF radio frequency biased tipped electrode and grounded ring is selected based upon the minimum breakdown voltage of said at least one precursor gas determined by Paschen curve of said precursor gas;
a dielectric tube enclosing an electrode that is coupled to a VHF radio frequency power source, the electrode having a pointed tip that has a variable distance between the tip and a VHF radio frequency powered ring operated in a push-pull (180° out of phase);
at least two parallel plates coupled to the VHF radio frequency power source so radio frequency power is delivered to said at least one precursor gas by an electric field formed between said at least two parallel plates by the VHF radio frequency power source;
at least one inductive coil coupled to the VHF radio frequency power source so that radio frequency power is delivered to said at least one precursor gas by an electric field formed by the inductive coil; or
a flow-through showerhead design in which a VHF radio frequency biased up-stream porous electrode plate is separated from a down stream porous electrode plate, with the pores of the plates aligned with one another, and wherein the down stream porous electrode plate is grounded or biased by VHF radio frequency operated in a push-pull manor (180° out of phase) relative to the up stream porous plate.

9. The system of claim 9, wherein the distance separating the up stream and down stream porous electrode plates is variable and filled with said at least one precursor gas or a dielectric media.

10. The system of claim 1, wherein the VHF radio frequency power source is configured to supply radio frequency power at a variable radio frequency, and wherein the radio frequency used to generate the plasma is selected based on measurements of a plurality of coupling efficiencies between the VHF radio frequency power source and the plasma at a plurality of radio frequencies and selected based on at least one of the plasma residence time, particle nucleation residence time, mean particle size, particle size distribution, and agglomeration kinetics in said at least on precursor gas.

11. The system of claim 10, wherein the VHF radio frequency power source can be in-situ frequency tuned to maximize the power coupling efficiency to said at least one precursor gas and a dielectric tube pressure.

12. The system of claim 11, wherein the VHF radio frequency power source is configured to provide at least one of:
continuous radio frequency power to the plasma generated by said precursor gas or gases;
pulsed radio frequency power by modulating the amplitude of the radio frequency power;
pulsed radio frequency power by modulating the frequency of the radio frequency power; or
pulsed radio frequency power in alternating on and off states.

13. The system of claim 1, wherein the coupled VHF radio frequency power source to plasma discharge has a power density from 3 to 800 W/cm².

14. The system of claim 1, wherein the chamber contains a chuck used to hold a substrate, and wherein the chuck is configured to provide at least one of:
a variable speed rotation;
variable position relative to the VHF radio frequency source; temperature controlled in the range −15° C. to 300° C.;
a direct current bias;
a radio frequency bias; or
load lockable capability.

15. The system of claim 1, wherein the chamber comprises at least one of:
a secondary 13.56 MHz plasma system for in-situ gas phase functionalization of nanoparticles synthesized in the up stream VHF radio frequency plasma; or
a thermal chemical vapor deposition source for in-situ gas phase functionalization of nanoparticles synthesized in the up stream VHF radio frequency plasma.

16. The system of claim 1, wherein the substrate is at least one of:
a roll-to-roll material;
a vacuum compatible solid; or
a vacuum compatible liquid.

17. The system of claim 1, wherein the nanoparticles synthesized in the up stream VHF radio frequency discharge are evacuated out of the low pressure chamber and brought to atmospheric pressure in an aerosol.

18. A method of producing core/shell nanoparticles, comprising:
providing a VHF radio frequency low pressure glow discharge of at least one precursor gas, wherein the VHF radio frequency is selected based on the plasma power coupling efficiency between the VHF radio frequency power source and the plasma;
dissociating said at least one precursor gas in the VHF plasma to nucleate and grow a nanoparticle core; and
growing a shell on the surface of the synthesized nanoparticles, wherein the shell is either inorganic or organic.

19. The method of claim 19, wherein the VHF radio frequency low pressure discharge is pulsed via at least one of amplitude modulation, frequency modulation, or alternating on and off states to control the plasma's high ion energy and density resident times to control at least one of the plasma residence time, core nanoparticle nucleation residence time, mean core nanoparticle size, core nanoparticle size distribution, and agglomeration kinetics in said at least on precursor gas, and wherein the synthesized core nanoparticle is coated by a shell in the gas phase.

20. A method of producing combined nanoparticle/amorphous thin films, comprising:
mixing at least one nanoparticle precursor gas with at least one amorphous thin film precursor gas in a VHF radio frequency low pressure plasma discharge, said at least one nanoparticle precursor gas comprising at least one of SiH₄, SiCl₄, H₂SiCl₂, BCl₃, B₂H₆, PH₃, GeH₄, or GeCl₄.

21. A method of producing doped nanoparticle/amorphous thin films, comprising:
mixing at least one nanoparticle precursor gas and at least one amorphous thin film precursor gas with at least one dopant precursor gas in a VHF radio frequency low pressure plasma discharge, said at least one nanoparticle precursor gas comprising at least one of SiH₄, SiCl₄, H₂SiCl₂, BCl₃, B₂H₆, PH₃, GeH₄, or GeCl₄.
